(19) United States
(12) Patent Application Publication
(10) Pub. No.: US 2024/0081038 A1
(43) Pub. Date: Mar. 7, 2024

(54) Systems, Devices, and Methods of Charge-Based Storage Elements

(71) Applicant: Arm Limited, Cambridge (GB)

(72) Inventors: Divya Madapusi Srinivas Prasad, San Jose, CA (US); David Victor Pietromonaco, Cupertino, CA (US); Brian Tracy Cline, Austin, TX (US); Mudit Bhargave, Austin, TX (US)

(21) Appl. No.: 17/902,798

(22) Filed: Sep. 2, 2022

(51) Int. Cl. H01L 27/108

(52) U.S. Cl. CPC H01L 27/108

(57) ABSTRACT

According to one implementation of the present disclosure, a circuit structure is configured to store charge in a charge-based storage element, where the charge-based storage element is disposed at least partially in a shallow-trench-isolation (STI) region of the circuit. According to one implementation of the present disclosure, a method includes: providing a circuit structure disposed on a substrate and a shallow-trench-isolation (STI) region of a circuit; forming an opening of the substrate and the STI region by removing a portion of the substrate and STI region; placing a first liner material in the opening and on remaining portions of the substrate and the STI region; and depositing a first metal layer in the opening on the first liner material.

### I. FIELD

The present disclosure is generally related to systems, devices and methods of charge-based storage elements.

### II. DESCRIPTION OF RELATED ART

Advances in technology have resulted in smaller and/or more powerful computing devices, with ever growing power, performance, area and cost (PPAC) demands. For example, a variety of portable personal computing devices, including wireless telephones, such as mobile and smart phones, tablets and laptop computers are small, lightweight, and easily carried by users. These devices can communicate voice and data packets over wireless networks. Further, many such devices incorporate additional functionality, such as a digital still camera, a digital video camera, a digital recorder, and an audio file player. Also, such devices can process executable instructions, including software applications, such as a web browser application, that can be used to access the Internet. As such, these devices can include significant computing and networking capabilities. Accordingly, there is an ongoing need in the art for memory optimization, and improvement in power, performance, area and cost for various memory operations.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIGS. 1A-1B are diagrams in accordance with various implementations described herein.

FIGS. 2A-2B are diagrams in accordance with various implementations described herein.

FIGS. 3A-3B are diagrams in accordance with various implementations described herein.

FIG. 4 is a diagram illustrating certain aspects of various implementations described herein.

FIG. 5 is a diagram illustrating certain aspects of various implementations described herein.

FIG. 6 is a diagram illustrating certain aspects of various implementations described herein.

FIG. 7 is a flowchart illustrating certain aspects of various implementations described herein.

FIG. 8 is a flowchart illustrating certain aspects of various implementations described herein.

FIG. 9 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration and many of the units are normalized to showcase relative trends. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. While certain diagrams as illustrated herein are shown in two-dimensions, aspects of the diagrams as provided herein are to be understood to be three-dimensional having X, Y and Z axes. Therefore, the following detailed description is not to be taken to limit claimed subject matter and/or equivalents.

### IV. DETAILED DESCRIPTION

Particular implementations of the present disclosure are described below with reference to the drawings. In the description, common features are designated by common reference numbers throughout the drawings.

According to one implementation of the present disclosure, a circuit structure is configured to store charge in a charge-based storage element, where the charge-based storage element is disposed at least partially in a shallow-trench-isolation (STI) region of the circuit.

According to one implementation of the present disclosure, a method includes: providing a circuit structure disposed on a substrate and a shallow-trench-isolation (STI) region of a circuit; forming an opening of the substrate and the STI region by removing a portion of the substrate and STI region; placing a first liner material in the opening and on remaining portions of the substrate and the STI region; and depositing a first metal layer in the opening on the first liner material, where the substrate is coupled to ground, and where an input voltage is coupled to the circuit structure.

According to one implementation of the present disclosure, a method includes: providing a memory cell structure disposed on a substrate and a shallow-trench-isolation (STI) region; forming one or more charge-based storage elements in the substrate and the STI region to store data of the memory cell structure; and manufacturing, or causing to be manufactured, a memory device having the memory cell structure with the one or more charge-based storage element formed in the substrate and the STI region or fin-cut region.

Traditionally, static-random access memory (SRAM)-based memory has been preferred due its speed and reliability in memory devices. Another alternative for memory design includes the usage of eDRAM (i.e., embedded of dynamic random-access-memory). However, at room temperature operation, eDRAM may not be attractive. As a characteristic, eDRAM leaks current rapidly, and thus its retention time (i.e., the capacity to hold memory data) would be a short timeframe in microseconds. Hence, challenges to the implementation of eDRAM include the frequent requirement for refresh operations, and that such operations for refresh or dynamic refresh may be energy intensive. In comparison to SRAM, eDRAM is smaller and thus, would utilize less transistors (e.g., three transistors or less for eDRAM, while SRAM would require six transistors). Further, as another feature, in eDRAM, there are separate read and write transistors, allowing for read and write operations to be performed separately. In certain implementations, the use of eDRAM (i.e., embedded of dynamic random-access-memory) (e.g., a gain cell DRAM) for memory in computing devices can be attractive because it utilizes lower energy, lower static power, and sometimes lower dynamic power as well.

As may be appreciated, for CMOS-compatible technology, trenches that contain conductor material including barrier/liner (for the protection of surrounding dielectric material) have been utilized for power and ground wires (in order to reduce IR drop). In addition, for advance node technologies, shallow-trench-isolation (STI) regions between transistors may be utilized to create a trench for buried power rails. Moreover, recently, gain-cell (GC) eDRAMs have increased in popularity due to their low area requirements in comparison to SRAMs, but are also CMOS-technology compatible (e.g., such memory can reside on a same die it would not require deep trench capacitors or any other special capacitors for off-chip DRAM memories).

Advantageously, taking the above considerations into account, inventive aspects of the present invention allow for enhanced memory reliability while implementing buried rail technology. For example, such inventive aspects of the present invention include circuits, systems, and methods to provide for an increase of stored charge (i.e., SN) for memory, latches, and flip-flops by utilizing buried rail technology. Specifically, the increase in stored charge is by including locations where stored charge may be added to boost (i.e., enhance) stored charge.

In certain implementations, shallow-trench-isolation (STI) regions for depositing metal-dielectric-metal can be utilized to enhance stored charge for memory (e.g., eDRAM) that suffers from low retention time due to utilizing on-chip capacitors to store charge. Advantageously, such inventive aspects would enhance retention times. In certain implementations, fin-cut regions (typically used for cutting the diffusion/active region) may be utilized for depositing metal-dielectric-metal to form capacitors (e.g., eDRAM) that suffer with low retention time due to utilizing on-chip capacitors to store charge. Advantageously, such inventive aspects, as well, would enhance retention times. In certain implementations, STI regions and the gate-cut regions in combination may be utilized for further enhancement of capacitance. In addition, the STI and fin-cut regions may be implemented to deposit charge-based storage elements (e.g., capacitors) through CMOS-compatible methods in order to enhance soft-error rate (SER) robustness for both SRAM and eDRAM.

Advantageously, schemes and techniques described herein provide the benefit of a “2×” increase in storage node capacitance such that a “2×” improvement or more in retention time may be realized for an eDRAM. Moreover, a realized “2×” increase in storage node charge (e.g., in SRAM) would also improve SER by greater than “2×” (e.g. as the SER would be exponentially dependent on stored charge Q as described herein).

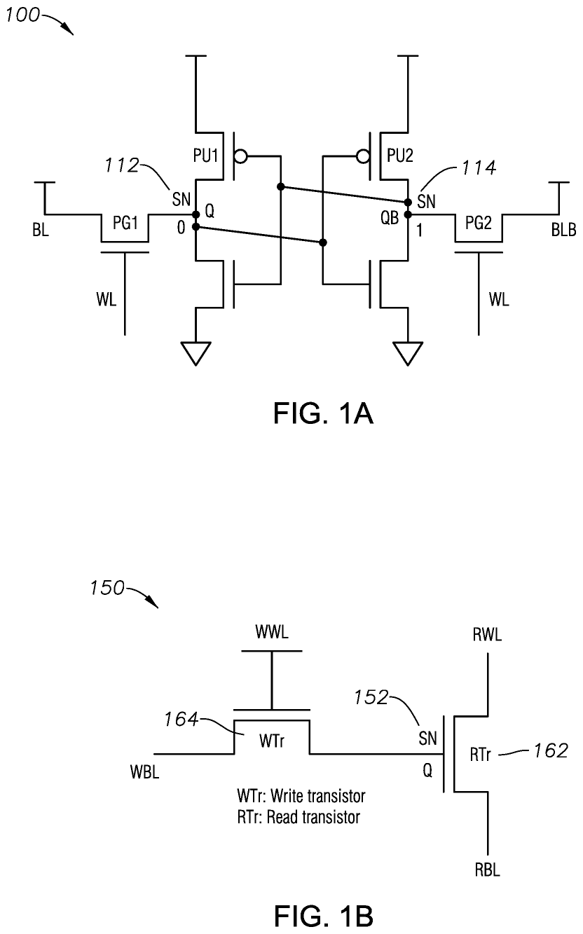

With reference to FIGS. 1A-1B, 2A-2B, 3A-3B, 4, 5, in certain implementations, a circuit structure (e.g., flip-flop, memory bitcells, a memory structure) may be configured to store charge in a charge-based storage element (e.g., capacitor), where the charge-based storage element is formed (or located, disposed) at least partially in a shallow-trench-isolation (STI) region of the circuit.

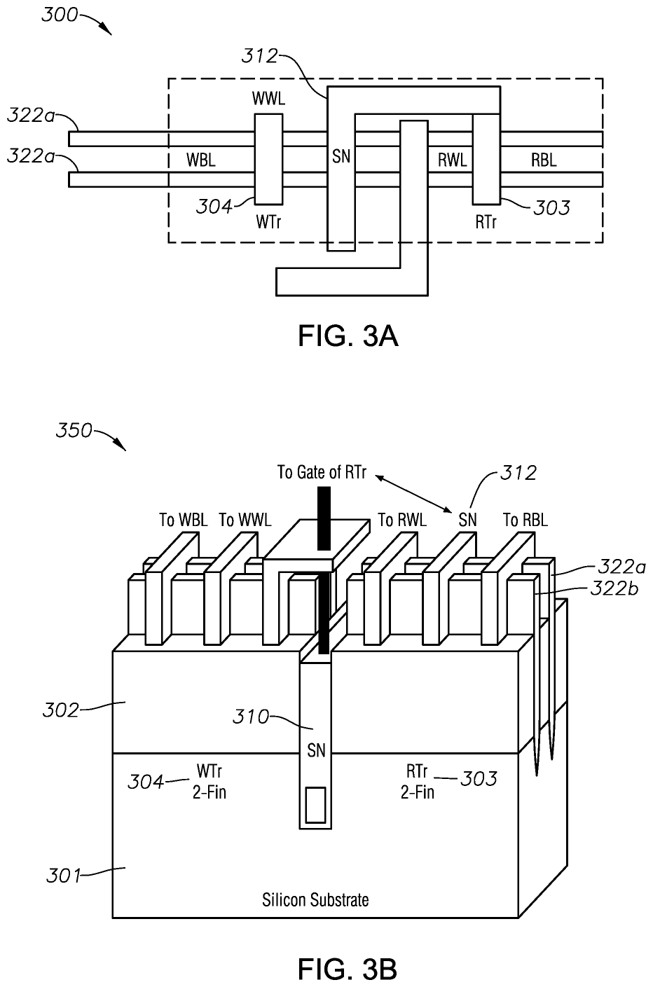

Referring to FIGS. 1A-1B, example circuit structures 100, 150 are shown. For example, diagrams of an example SRAM circuit structure 100 (FIG. 1A) and eDRAM circuit structure 150 (FIG. 1B) are illustrated. The circuit structures 100, 150 include example representative memory structures that can be coupled to an STI region (e.g., 112, 114, 152) and/or fin-cut area (if formed outside of the STI region) (e.g., the storage node (SN) 312 in FIG. 3) that can be configured to store data as charge. In other examples (not shown), flip-flops, latches, or any other memory structure that can be configured to store data as charge may be utilized and coupled to an STI region and substrate.

With reference to FIG. 1A, an example SRAM circuit structure 100 is shown. As illustrated, the SRAM circuit structure 100 is a two NMOS (e.g., PG1, PG2) and two PMOS (e.g., PU1, PU2) SRAM circuit. The circuit 100 further includes at least first and second internal nodes (Q, QB), and wherein the charge-based storage element includes at least one capacitor that is formed on the first and second internal nodes (Q, QB). For example, the first and second internal nodes (Q, QB) are proximate to, or may correspond to, storage nodes (SN) 112, 114. As may be appreciated, FIG. 1A illustrates one example of how a capacitor may be formed. In other implementations, as described with reference to FIGS. 1B, 2A, 2B, 3A, 3B, 4, 5, and 6, other examples are shown for forming capacitors.

With reference to FIG. 1B, as an example eDRAM circuit structure 150, a NMOS-based 2T gain-cell eDRAM is shown. In certain instances, the eDRAM circuit structure 150 can include dual ports for read and write, through a read transistor (RTr) 162 and write transistor (WTr) 164, respectively. For example, a stored charge would be present on a storage node SN 152 that would correspond to a gate capacitance of the read transistor (RTr) 162.

Correspondingly, such charge would largely leak through the write transistor (WTr) 164, even when the bit-cell is not in use, leaving the write transistor (WTr) 164 to leak at subthreshold, and the storage node SN 152 would, thus, remain reliable only for a period of time called “retention time”.

As illustrated, the write transistor (WTr) 164 can be configured to act as a pass gate to write a value on a write bitline (WBL) to the storage node (SN) 152 (e.g., the gate node of the read transistor (RTr) 162) when the write word line (WWL) is activated. As may be appreciated, the greater a charge on the storage node (SN) 152, the higher the “retention time” (i.e., the more time available until a stored charge would be destroyed). Hence, advantageously, inventive aspects as described herein provide for the capability to increase the charge capacity on various storage node locations.

Also, in certain implementations, in FIG. 1B, the read transistor (RTr) 162 can be configured to act as a read-only node, such that when the read word line (RWL) is pulsed, the pulse is reflected on the read bit line (RBL) if, for example, the storage node (SN) 152 holds a digital logic “1”. If not, and the storage node (SN) 152 holds a digital “0”, no change would be reflected in the read bit line (RBL). For instance, the drain contact of the write transistor (WTr) 164 would need to be “cut”, and a separate connection would be provided to connect the write transistor (WTr) 164 drain contact to the gate-contact storage node (SN) 152 of the read transistor (RTr) 162. In other implementations (not shown), a 3T gain-cell eDRAM may be utilized (e.g., including two read transistors and one write transistor). In various implementations, such eDRAM circuits, would hold a charge at the storage node (SN) 152 that is equivalent to a gate capacitance of the read transistor (RTr) 162.

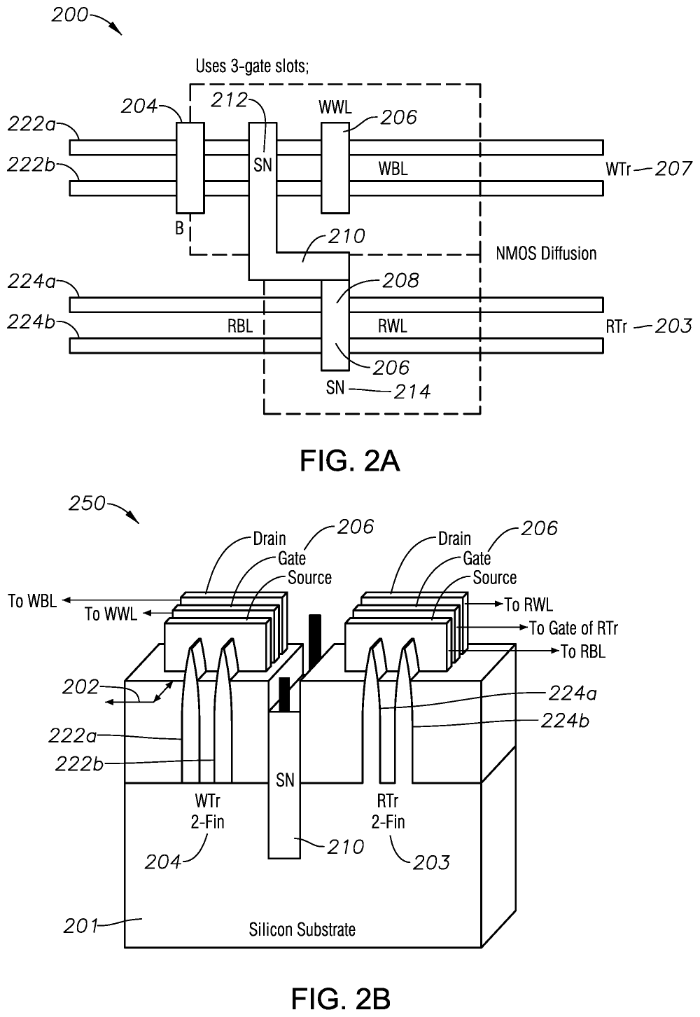

Referring to FIGS. 2A and 2B, top (FIG. 2A) and side (FIG. 2B) views is shown of an example eDRAM circuit (e.g., 2T gain-cell eDRAM layout). As illustrated, FIGS. 2A-2B illustrates the utilization of buried rail technology upon a write transistor of an eDRAM circuit. Advantageously, according to inventive aspects, when applied to a 2T gain-cell eDRAM, the write transistor (WTr) may implement buried technology as a capacitor. In various implementations (as described herein), the capacitor can be either implemented in parallel or perpendicular (as illustrated in FIGS. 2A and 2B) to the gate 204, 206.

As illustrated, in FIG. 2A, a top view of the 2T gain cell eDRAM layout is shown with two-fin transistors (222a, 222b, 224a, 224b). In FIG. 2B, a three-dimensional representation depicts a storage node (SN) trench 210 perpendicular to the gate/poly 206. Advantageously, the storage node (SN) trench 210 may be configured to provide enhanced buried trench stored charge. In certain examples, utilization of the buried trench can be as the capacitor from the storage node (SN) metal-liner-silicon-substrate or in fabrication of the capacitor in the storage node (SN) trench. In certain implementations, as shown, the trench 210 may be metallic and would contain barrier/liner non-conducting material at the interface of the storage node (SN) 210 and the silicon substrate 201. In various implementations, the eDRAM can be configured such that a buried trench/capacitor 210 may be parallel to the fins (222a, 222b, 224a, 224b) and perpendicular to the gate 206 to enhance the storage node SN (e.g., coupled on storage node 210, 212, 214).

For example, in certain implementations, the charge-base storage element 210 comprises one or more capacitors, where at least one capacitor of the one or more capacitors can be formed (e.g., disposed, located) in at least one of a buried rail trench 210 (e.g., typically in the perpendicular direction to the fin-cut or a gate-cut region (corresponding at least partially to the shallow-trench-isolation (STI) region). In certain examples, as illustrated, the at least one capacitor is formed on a storage node (SN) 210, 212, 214 of the circuit, where the storage node is positioned in one or both of the buried rail trench 210 and the fin-cut region of the circuit. As may be appreciated, the fin-cut region includes a region between active fin shapes (where “active” refers to where a transistor would be made). In certain other examples, the at least one capacitor is formed in the STI region and a silicon substrate region of the circuit.

In certain cases, for example, the at least one capacitor is formed perpendicular to a gate layer (i.e., transistor-gate layer) configured to form respective gates of first transistor and second transistors. In other cases, for example, wherein the at least one capacitor is formed parallel to a gate layer (i.e., transistor-gate layer) configured to form respective gates of first transistor and second transistors. In certain implementations, the circuit structure configured for charging in a charge-based storage element may be a memory bit-cell such as: an eDRAM gain-cell (e.g., 2T or 3T) or an SRAM.

Referring to FIGS. 3A-3B, an example eDRAM layout 300, 350 is shown in top view (300) and 3D perspective view (350) according the example implementations. As illustrated, the layouts 300, 350 illustrates a cut-region 312 between a drain contact of the write transistor (WTr) 302, and the gate contact of read transistor (RTr) 303 to deposit a capacitor, and enhance the storage node (SN) 312 charge of the eDRAM 300, 350. Hence, such a “cut” area parallel to the poly and separating the storage node (SN) and a read word line (RWL) contact may be utilized to deposit a capacitor in the shallow-trench-isolation (STI) region of the circuit.

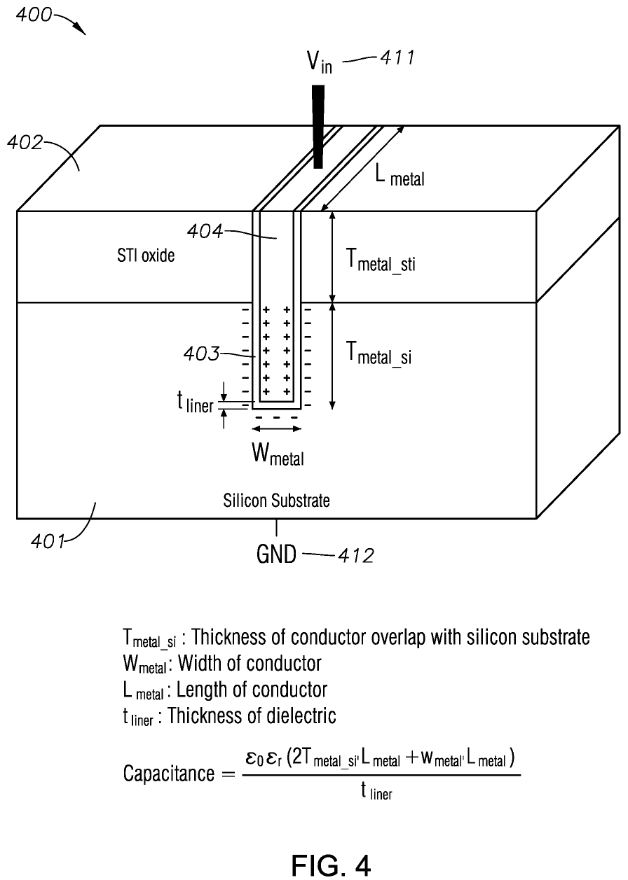

Referring to FIG. 4, an example portion of a circuit layout 400 (i.e., circuit layout, circuit structure) is shown according to example implementations. As illustrated, the circuit layout 400 is an example representation of utilizing a buried rail trench as a capacitor and may be implementable with circuits in FIGS. 1A-B, 2A-2B, and 3A-3B. As illustrated, the circuit layout 400 includes a silicon substrate layer 401 (i.e., silicon (Si) bulk layer), an shallow-trench-isolation (STI) oxide layer 402, an dielectric barrier-liner 403 (e.g., oxide/barrier liner material, etc.), and a shallow-trench-isolation (STI) region 404 (e.g., trench, metal conductor) of the circuit 400. In addition, in certain implementations, V 1 pin 411 may be coupled to the respective transistors (not shown in FIG. 4 but implementable with reference to FIGS. 1A-B, 2A-2B, and 3A-3B), while the silicon substrate layer 401 may be coupled to ground (GND) 412.

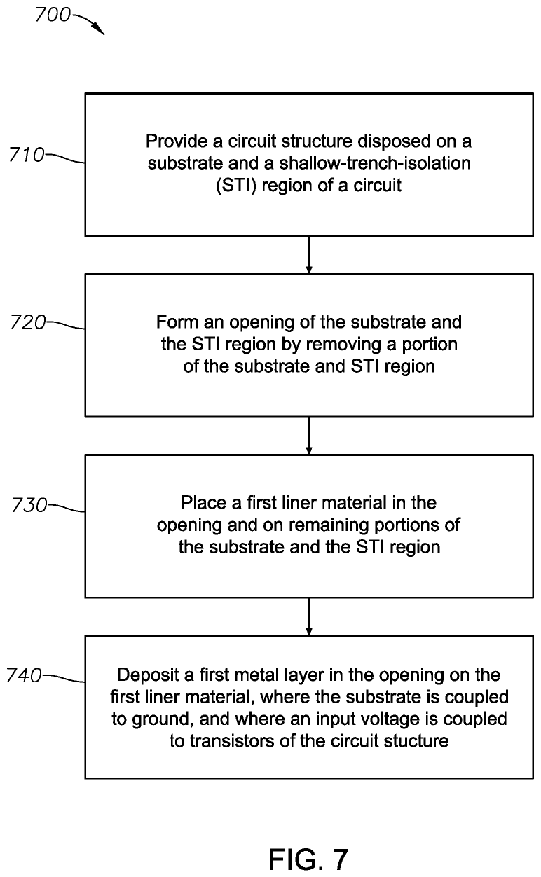

As may be appreciated, advantageously, the circuit layout 400 may be implemented to include a trench 404 of metal material and would be protected from the surrounding silicon bulk layer 401 using the oxide/barrier liner material 403 (e.g., as described with reference to the process in FIG. 7) to ensure reliability.

Advantageously, in an example implementation, an approximate estimation of capacitance (e.g., parallel plate capacitor) (e.g., in addition to a gate capacitance of a read transistor (RTr) of the circuit structure 400 may be computed with the following equation below where: T_{metal_si} corresponds to a thickness of metal conductor 404 overlap with the silicon substrate layer 401; Wₘₑₜₐₗ corresponds to a width of the metal conductor 404; Lₘₑₜₐₗ corresponds to a length of the metal conductor 404; and to tₗᵢₙₑᵣ corresponds to a thickness of the dielectric barrier-liner 403.

$$Capacitance = \frac{{ε}_{0} {ε}_{r} ( 2 {T}_{metal \_ Si} , {L}_{metal} + {w}_{metal} , {L}_{metal} )}{{t}_{liner}}$$

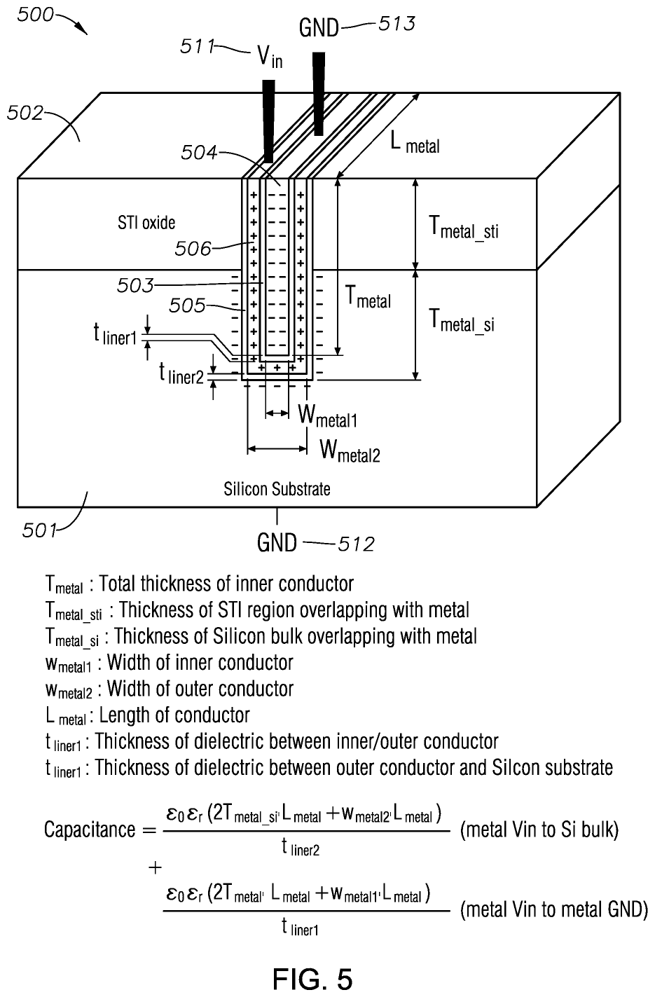

Referring to FIG. 5, an example portion of a circuit layout 500 (i.e., circuit layout, circuit structure) is shown according to example implementations. As illustrated, the circuit layout 500 is an example representation of utilizing a buried rail trench as a capacitor and may be implementable with circuits in FIGS. 1A-B, 2A-2B, and 3A-3B. As illustrated, the circuit layout 500 includes a silicon substrate layer 501 (i.e., silicon (Si) bulk layer), an shallow-trench-isolation (STI) oxide layer 502, an inner dielectric barrier-liner 503 (e.g., oxide/barrier liner material, etc.), an outer dielectric barrier-liner 505 (e.g., oxide/barrier liner material, etc.), a first shallow-trench-isolation (STI) region 506 (e.g., first metal conductor, outer conductor), and a second shallow-trench-isolation (STI) region 504 (e.g., second metal conductor, inner conductor) of the circuit 500. In addition, in certain implementations, as an example: Vi n pin 511 may be coupled to the respective transistors (e.g., not shown in FIG. 5 but implementable with reference to FIGS. 1A-B, 2A-2B, and 3A-3B) and to a metal conductor (e.g., first metal conductor 506); the silicon substrate layer 501 may be coupled to ground (GND) 512; and the second metal conductor 504 may be coupled to ground (GND) 513.

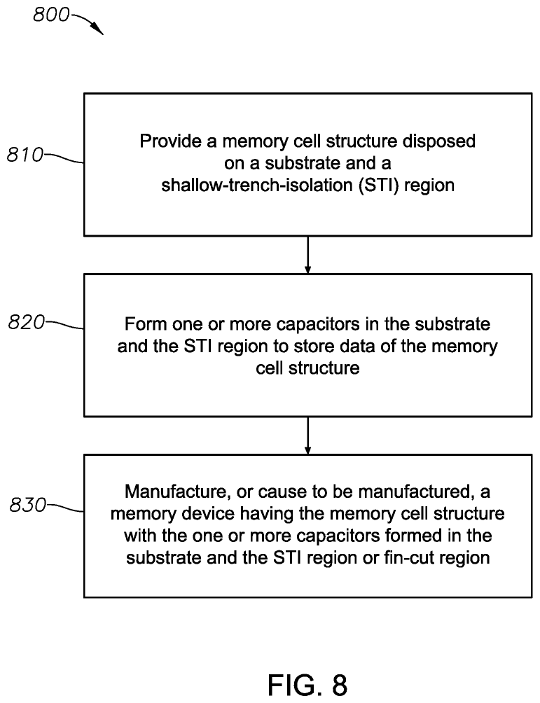

As may be appreciated, advantageously, the circuit layout 500 may be implemented to include a trench of two metal conductors and two dielectric layers to allow for increased capacitance in the storage node (SN) as permitted by manufacturing process (e.g., with reference to FIGS. 7 and 8).

Advantageously, first and second conductors 506, 504 would be protected from the surrounding silicon bulk layer 501 using the first and second oxide/barrier liner materials 505, 503 (as described with reference to the process in FIG. 7) to ensure reliability. Advantageously, in an example implementation, an approximate estimation of capacitance (e.g., parallel plate capacitor) (e.g., in addition to a gate capacitance of a read transistor (RTr) of the circuit structure 500 may be computed with the following equation below where: Tₘₑₜₐₗ corresponds to a total thickness of an inner conductor (i.e., second metal conductor) 504; T_{metal_sti} corresponds to a thickness of STI region 502 overlap with a first portion of the outer conductor (i.e., first metal conductor) 506; T_{metal_si} corresponds to a thickness of the silicon substrate layer 501 overlap with a second portion of the outer conductor (i.e., first metal conductor) 506; Wₘₑₜₐₗ₁ corresponds to a width of the inner metal conductor 504; Wₘₑₜₐₗ₂ corresponds to a width of the outer metal conductor 506; Lₘₑₜₐₗ corresponds to a width of the conductor (504, 506); tₗᵢₙₑᵣ₁ corresponds to a thickness of the inner dielectric barrier-liner 503 (e.g., between the inner and outer conductors 504, 506), and tₗᵢₙₑᵣ₂ corresponds to a thickness of the outer dielectric barrier-liner 505 (e.g., between the outer conductor 506 and the silicon substrate 501).

$$Capacitance = \frac{{ε}_{0} {ε}_{r} ( 2 {T}_{metal \_ Si} , {L}_{metal} + {w}_{metal 2} , {L}_{metal} )}{{t}_{liner 2}} + \frac{{ε}_{0} {ε}_{r} ( 2 {T}_{metal} , {L}_{metal} + {w}_{metal 1} , {L}_{metal} )}{{t}_{liner 2}}$$

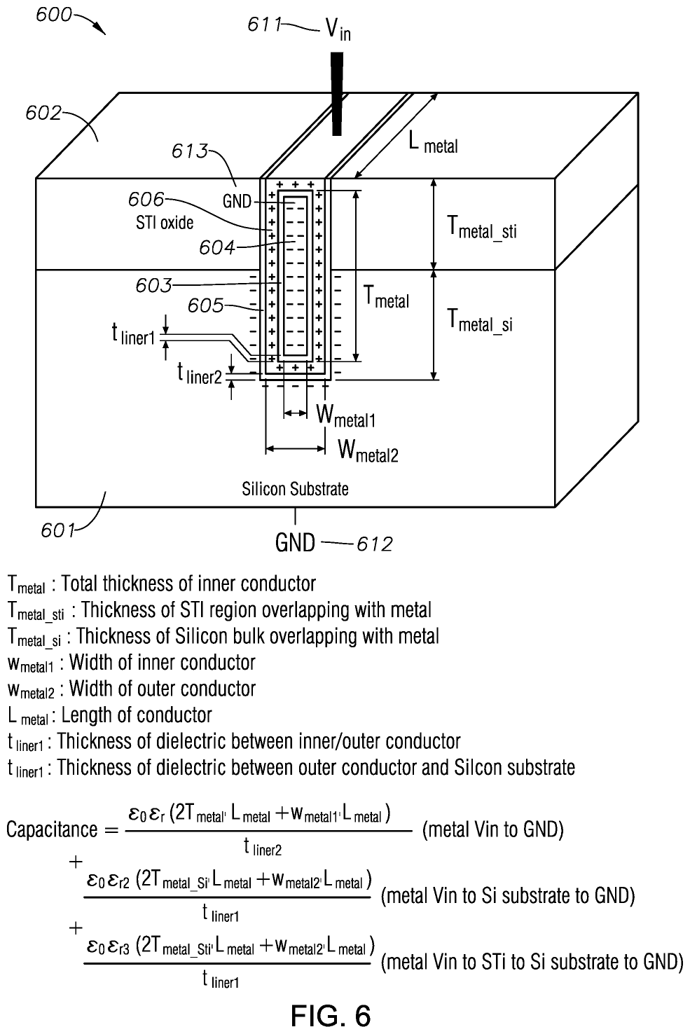

Referring to FIG. 6, an example portion of a circuit layout 600 (i.e., circuit layout, circuit structure) shown according to example implementations. As illustrated, the circuit layout 600 is an example representation of utilizing a buried rail trench as a capacitor and may be implementable with circuits in FIGS. 1A-B, 2A-2B, and 3A-3B. As illustrated, the circuit layout 600 includes a silicon substrate layer 601 (i.e., silicon (Si) bulk layer), an shallow-trench-isolation (STI) oxide layer 602, an inner dielectric barrier-liner 603 (e.g., oxide/barrier liner material, etc.), an outer dielectric barrier-liner 605 (e.g., oxide/barrier liner material, etc.), a first shallow-trench-isolation (STI) region 606 (e.g., first metal conductor, outer conductor) (e.g., coupled to or corresponding to Vin 611), and a second shallow-trench-isolation (STI) region 604 (e.g., second metal conductor, inner conductor) (e.g., coupled to or corresponding to GND 612) of the circuit 600. In addition, in certain implementations, Vi n pin 611 may be coupled to the respective transistors (not shown in FIG. 6 but implementable with reference to FIGS. 1A-B, 2A-2B, and 3A-3B) and to a metal conductor (e.g., first metal conductor 606), while the silicon substrate layer 601 may be coupled to ground (GND) 612.

As may be appreciated, advantageously, the circuit layout 600 (i.e., circuit structure) may be implemented to include a trench of two metal conductors and two dielectric layers to allow for increased capacitance in the storage node (SN) as permitted by manufacturing process. However, in contrast to the circuit layout FIG. 5, the inner conductor 604 would be coupled to ground (GND) 613, while in FIG. 6, it would be exposed either at a top portion or a bottom portion a multiple positions across the layout 600 for external connectivity to ensure a sufficient insulation with the Vin 611 conductor 606 surrounding it.

Advantageously, first and second conductors (i.e., outer and inner conductors) 606, 604 would be protected from the surrounding silicon bulk layer 601 using the first and second oxide/barrier liner materials 603, 605 (as described with reference to the process in FIG. 7) to ensure reliability. Advantageously, in an example implementation, an approximate estimation of capacitance (e.g., parallel plate capacitor) (e.g., in addition to a gate capacitance of a read transistor (RTr) of the circuit structure 600 may be computed with the following equation below where: Tₘₑₜₐₗ corresponds to a total thickness of an inner conductor (i.e., second metal conductor) 604; T_{metal_sti} corresponds to a thickness of STI region 602 overlap with a first portion of the outer conductor (i.e., first metal conductor) 606; T_{metal_si} corresponds to a thickness of the silicon substrate layer 601 overlap with a second portion of the outer conductor (i.e., second metal conductor) 606; Wₘₑₜₐₗ₁ corresponds to a width of the inner metal conductor 604; Wₘₑₜₐₗ₂ corresponds to a width of the outer metal conductor 606; Lₘₑₜₐₗ corresponds to a width of the conductor (604, 606); tₗᵢₙₑᵣ₁ corresponds to a thickness of the inner dielectric barrier-liner 603 (e.g., between the inner and outer conductors 604, 606), and tₗᵢₙₑᵣ₂ corresponds to a thickness of the outer dielectric barrier-liner 605 (e.g., between the outer conductor 606 and the silicon Substrate 601).

$$Capacitance = \frac{{ε}_{0} {ε}_{r 1} ( 2 {T}_{metal} , {L}_{metal} + 2 {w}_{metal 1} , {L}_{metal} )}{{t}_{liner 1}} + \frac{{ε}_{0} {ε}_{r 2} ( 2 {T}_{metal \_ si} , {L}_{metal} + {w}_{metal 2} , {L}_{metal} )}{{t}_{liner 1}} + \frac{{ε}_{0} {ε}_{r 3} ( 2 {T}_{metal \_ sti} , {L}_{metal} + {w}_{metal 2} , {L}_{metal} )}{{t}_{liner 1}}$$

Referring to FIG. 7, an example flowchart 700 according to example implementations is shown. As illustrated, the flowchart 700 corresponds to a procedure and methodology for implementation of a capacitor in an STI region (e.g., a “repurposed” STI region) and substrate. Advantageously, in various implementations, the method 700 would ensure retention-time preservation for eDRAM and SRAM improvements in power, performance, area, and cost (PPAC). The flowchart 700 may be implementable with circuit representations 100, 150, 200, 250, 300, 350, 400, 500, 600 and 900 with reference to FIGS. 1A-1B, 2A-2B, 3A-3B, 4, 5, 6, and 9 as described herein.

At block 710, the method 700 includes: providing a circuit structure (e.g., a memory cell structure) disposed on a substrate and a shallow-trench-isolation (STI) region of a circuit. For example, with reference to implementations in FIGS. 1A, 1B, 2A, 2B, 3A, 3B, 4-6, and 9 as described herein, a circuit structure (e.g., as shown as 100, 150, 200, 250, 300, 400, 500, 600, and 900) (e.g., a memory cell structure, flip-flop, or latch) disposed on a substrate (e.g., as shown as 201, 301, 401, 501, 601) and a shallow-trench-isolation (STI) region (e.g., as shown as 202, 302, 402, 502, 602) of a circuit (e.g., an integrated circuit) may be provided.

At block 720, the method 700 includes: forming an opening (e.g., a trench) of the substrate and the STI region by removing (etching, cutting) a portion of the substrate and STI region. For example, with reference to implementations in FIGS. 1A, 1B, 2A, 2B, 3A, 3B, 4-6, and 9 as described herein, an opening (e.g., a trench opening (e.g., trench where conductors 210, 310, 404, 406, 504, 506, etc. are placed)) of the substrate (e.g., as shown as 301, 401, 501, 601) and the STI region (e.g., as shown as 202, 302, 402, 502, 602) by removing (etching, cutting) a portion of the substrate (e.g., as shown as 201, 301, 401, 501, 601) and STI region (e.g., as shown as 302, 402, 502, 602) may be formed.

At block 730, the method 700 includes: placing (e.g., inserting) a first liner material (e.g., oxide/barrier liner material, a first dielectric layer) in the opening and on remaining portions of the substrate and the STI region. For example, with reference to implementations in FIGS. 1A, 1B, 2A, 2B, 3A-3B, 4-6, and 9 as described herein, a first liner material (e.g., 403, 505, 605) (e.g., oxide/barrier liner material, a first dielectric layer) in the opening (e.g., trench where conductors 210, 310, 404, 406, 504, 506, etc. are placed) and on remaining portions of the substrate (e.g., as shown as 301, 401, 501, 601) and the STI region (e.g., as shown as 302, 402, 502, 602) may be placed (i.e., inserted).

At block 740, the method 700 includes: depositing a first metal layer in the opening on the first liner material, wherein the substrate is coupled to ground, and where an input voltage is coupled to (transistors of) the circuit structure. For example, with reference to implementations in FIGS. 1A, 1B, 2A, 2B, 3-6, and 9 as described herein, a first metal layer (e.g., 404, 506, 606) in the opening (e.g., trench where conductors 210, 310, 404, 406, 504, 506, etc. are placed) on the first liner material layer (e.g., 404, 506, 606), where the substrate (e.g., as shown as 301, 401, 501, 601 is coupled to ground (GND) (e.g., 412, 512, 612), and where an input voltage (Vin) is coupled to transistors (e.g., RTr and WTr) of the circuit structure (e.g., as shown as 100, 150, 200, 250, 300, 400, 500, 600, and 800) may be deposited.

In some implementations, forming of the opening (e.g., trench opening) includes removing a portion of a field effect transistor (FET) (e.g., fin-FET) (e.g., 222a, 222b, 322a, 322b). For example, with reference to implementations in FIGS. 2A, 2B, 3A-3B, portions of the FET transistors would be removed as well. In various implementations, the FET transistor may be fin-FET, gate-all-around (GAA) nanosheet FETs, or any similar FET.

In certain implementations, with reference to FIGS. 5 and 6, a second liner material (e.g., 503, 603) (e.g., oxide/barrier liner material, a second dielectric layer) in the opening and on the first metal layer (e.g., 506, 606) may be deposited (i.e., placed, inserted). In addition, a second metal layer (e.g., 504, 604) may be deposited in the opening on the second liner material (e.g., 503, 603), where the input voltage (Vin) is coupled to the first metal layer 506. In other implementations (not shown), the input voltage (Vin) may be coupled to the second metal layer (e.g., 504, 604).

In some implementations, with reference to FIG. 6, the method may include: the second metal layer 604 being enclosed (e.g., fully, substantially) within the second liner material 603. Also, the first metal layer 606 may be deposited on the second liner material 603, where the first metal layer 606 (i.e., first conductor) is separated (i.e., insulated) from the second metal layer 604 (i.e., second conductor). In addition, in such cases, a ground connectivity (GND) 613 corresponding to the second metal layer 604 may be configured for external connectivity at either upper or lower portions of the second metal layer 604.

Referring to FIG. 8, an example flowchart 800 according to example implementations is shown. As illustrated, the flowchart 800 corresponds to a procedure and methodology for fabrication of a capacitor in an STI region (e.g., a “repurposed” STI region). Advantageously, in various implementations, the method 700 would ensure retention-time preservation for eDRAM and SRAM improvements in power, performance, area, and cost (PPAC). The flowchart 800 may be implementable with circuit representations 100, 150, 200, 250, 300, 350, 400, 500, 600 and 900 with reference to FIGS. 1A-1B, 2A-2B, 3A-3B, 4, 5, 6, and 9 as described herein.

At block 810, the method 800 includes: providing a circuit structure (e.g., a memory cell structure) disposed on a substrate and a shallow-trench-isolation (STI) region of a circuit. For example, with reference to implementations in FIGS. 1A, 1B, 2A, 2B, 3A, 3B, 4-6, and 9 as described herein, a circuit structure (e.g., as shown as 100, 150, 200, 250, 300, 400, 500, 600) (e.g., a memory cell structure, flip-flop, or latch) disposed on a substrate (e.g., as shown as 301, 401, 501, 601) and a shallow-trench-isolation (STI) region (e.g., as shown as 302, 402, 502, 602) of a circuit (e.g., an integrated circuit) may be provided.

At block 820, the method 800 includes: forming one or more capacitors in the substrate and the STI region to store data of the memory cell structure. For example, with reference to implementations in FIGS. 1A, 1B, 2A, 2B, 3A, 3B, 4-6, and 9 as described herein, one or more capacitors (e.g., trench where conductors 210, 310, 404, 406, 504, 506, etc. are positioned) in the substrate (e.g., as shown as 201, 301, 401, 501, 601) and the STI region (e.g., as shown as 202, 302, 402, 502, 602) to store data of the memory cell structure (e.g., as shown as 100, 150, 200, 250, 300, 400, 500, 600) (e.g., an SRAM, eDRAM, etc.) may be formed (e.g., “buried”).

At block 830, the method 700 includes: manufacturing, or causing to be manufactured, a memory device having the memory cell structure with the one or more capacitors formed or buried or disposed in the substrate and the STI region or fin-cut region. For example, with reference to implementations in FIGS. 1A, 1B, 2A, 2B, 3A, 3B, 4-6, and 9 as described herein, a memory device (not shown) having the memory cell structure (e.g., as shown as 100, 150, 200, 250, 300, 400, 500, 600) with the one or more capacitors formed or buried or disposed in the (e.g., as shown as 201, 301, 401, 501, 601) and the STI region (e.g., as shown as 202, 302, 402, 502, 602) or fin-cut region (e.g., 312).

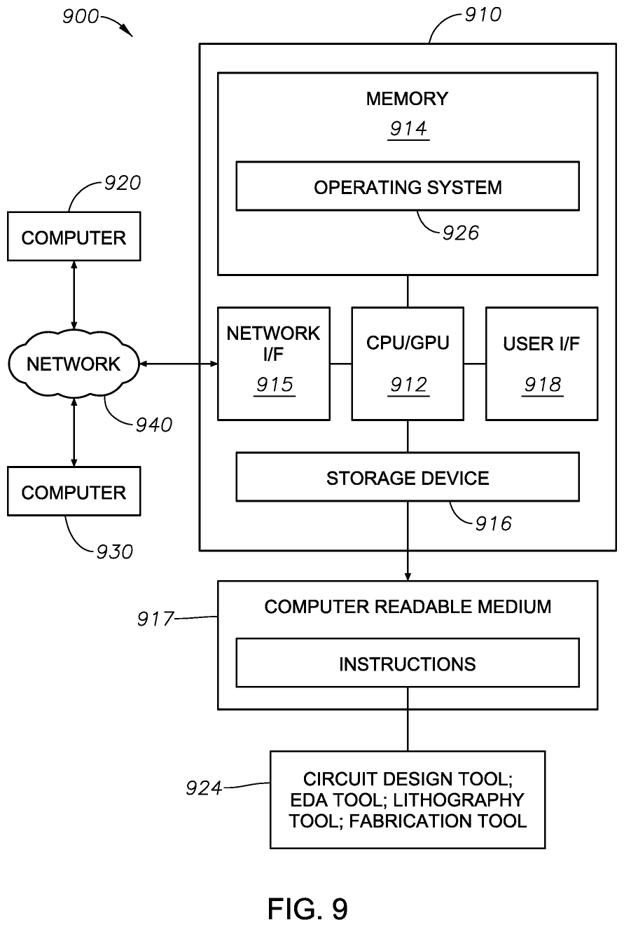

As may be appreciated, such steps as described herein may performed by various lithography and circuit generation methods and be performed by a manufacturing, lithography tool 924 as described with reference to FIG. 9.

FIG. 9 illustrates example hardware components in a computer system 900. In some implementations, the computer system 900 may be a memory compiler system. The system 900, in various implementations, can be utilized for or in concurrent operations to: generate, manufacture, or provide a circuit structure (e.g., a memory cell structure, latch, or flip-flop) disposed on a substrate and a shallow-trench-isolation (STI) region of a circuit (e.g., an integrated circuit, memory device), integrated circuit design, memory architecture output, logic design, memory macros, interconnect and back-end-of-line (BEOL) design; determine optimal transistor level, integrated circuit level, EDA optimization, system-level design and maximum frequency optimization, and multi-tier system level optimization. In certain implementations, the example computer system 900 (e.g., networked computer system and/or server) may include electronic tool(s) 924 (e.g., lithography tool, fabrication tool, electronic design automation tool (EDA) (e.g., layout generation and extraction tools, and device and process modelling tools, circuit design tools, etc.) and execute software based on the procedure as described with reference to at least methods 700, 800, and other methods as described throughout the disclosure and as referenced with reference to FIGS. 1-9. In certain implementations, the electronic tool(s) 924 may be included as a feature of an existing memory compiler software program allowing users to input power grid and cell layout criteria, and generate power grids and cell layouts accordingly.

In certain cases, the electronic tool 924 may provide generated computer-aided physical layout designs for memory architecture. The procedures 700, 800 (and other procedures discussed throughout the disclosure) may be stored as program code as instructions 917 in the computer readable medium of the storage device 916 (or alternatively, in memory 914) that may be executed by the computer 910, or networked computers 920, 930, other networked electronic devices (not shown) or a combination thereof. In certain implementations, each of the computers 910, 920, 930 may be any type of computer, computer system, or other programmable electronic device. Further, each of the computers 910, 920, 930 may be implemented using one or more networked computers, e.g., in a cluster or other distributed computing system.

In certain implementations, the system 900 may be used with semiconductor integrated circuit (IC) designs that contain all standard cells, all blocks or a mixture of standard cells and blocks. In a particular example implementation, the system 900 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 900 may be stored in one or more of memory 914 or storage devices 916 of computer 910 or in networked computers 920, 930.

In certain implementations, the system 900 may perform the following functions automatically or with variable user input: determination of read current requirements/thresholds (i.e., Iread), determination of leakage current requirements/thresholds (i.e., Ileak), identification of logic designs (i.e., periphery circuit designs (i.e., logic threshold voltages, threshold voltage implant layers)), determination of a desired threshold voltage-combination, determination of minimum voltage assist requirements (i.e., Vmin assist), identification of bit-cell types, determination of memory specific optimization modes (memory optimization mode), floor-planning, including generation of cell regions sufficient to place all standard cells; standard cell placement; power and ground net routing; global routing; detail routing and pad routing. In some instances, such functions may be performed substantially via user input control. Additionally, such functions can be used in conjunction with the manual capabilities of the system 900 to produce the target results that are required by a designer. In certain implementations, the system 900 may also provide for the capability to manually perform functions such as: cell region creation, block placement, pad and cell placement (before and after automatic placement), net routing before and after automatic routing and layout editing. Moreover, verification functions included in the system 900 may be used to determine the integrity of a design after, for example, manual editing, design rule checking (DRC) and layout versus schematic comparison (LVS).

In one implementation, the computer 900 includes a central processing unit (CPU) or graphical processing unit (GPU) 912 having at least one hardware-based processor coupled to a memory 914. The memory 914 may represent random access memory (RAM) devices of main storage of the computer 910, supplemental levels of memory (e.g., cache memories, non-volatile or backup memories (e.g., programmable or flash memories), read-only memories, or combinations thereof. In addition to the memory 914, the computer system 900 may include other memory located elsewhere in the computer 910, such as cache memory in the CPU 912, as well as any storage capacity used as a virtual memory (e.g., as stored on a storage device 916 or on another computer coupled to the computer 910).

The computer 910 may further be configured to communicate information externally. To interface with a user or operator (e.g., a circuit design engineer), the computer 910 may include a user interface (I/F) 918 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 910 may include a network interface (I/F) 915 which may be coupled to one or more networks 940 (e.g., a wireless network) to enable communication of information with other computers and electronic devices. The computer 910 may include analog and/or digital interfaces between the CPU 912 and each of the components 914, 915, 916, and 918. Further, other non-limiting hardware environments may be used within the context of example implementations.

The computer 910 may operate under the control of an operating system 926 and may execute or otherwise rely upon various computer software applications, components, programs, objects, modules, data structures, etc. (such as the programs associated with the procedures e.g., 700, 800, and related software). The operating system 928 may be stored in the memory 914. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 926 in the example of FIG. 9 is shown in the memory 914, but components of the aforementioned software may also, or in addition, be stored at non-volatile memory (e.g., on storage device 916 (data storage) and/or the non-volatile memory (not shown). Moreover, various applications, components, programs, objects, modules, etc. may also execute on one or more processors in another computer coupled to the computer 910 via the network 940 (e.g., in a distributed or client-server computing environment) where the processing to implement the functions of a computer program may be allocated to multiple computers 920, 930 over the network 940.

In example implementations, circuit macro diagrams have been provided in certain figures described herein, whose redundant description has not been duplicated in the related description of analogous circuit macro diagrams. It is expressly incorporated that the same cell layout diagrams with identical symbols and/or reference numerals are included in each of embodiments based on its corresponding figure(s).

Although one or more of FIGS. 1-9 may illustrate systems, apparatuses, or methods according to the teachings of the disclosure, the disclosure is not limited to these illustrated systems, apparatuses, or methods. One or more functions or components of any of FIGS. 1-9 as illustrated or described herein may be combined with one or more other portions of another of FIGS. 1-9. Accordingly, no single implementation described herein should be construed as limiting and implementations of the disclosure may be suitably combined without departing form the teachings of the disclosure.

Aspects of the present disclosure may be incorporated in a system, a method, and/or a computer program product. The computer program product may include a computer-readable storage medium (or media) having computer-readable program instructions thereon for causing a processor to carry out aspects of the present disclosure. The computer-readable storage medium can be a tangible device that can retain and store instructions for use by an instruction execution device. The computer-readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer-readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer-readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. For example, the memory 1514, the storage device 1516, or both, may include tangible, non-transitory computer-readable media or storage devices.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry, field-programmable gate arrays (FPGA), or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, such that the instructions, which execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all of such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit comprising:
a circuit structure configured to store charge in a charge-based storage element, wherein the charge-based storage element is disposed at least partially in a shallow-trench-isolation (STI) region of the circuit.

2. The circuit of claim 1, wherein the charge-base storage element comprises one or more capacitors, and wherein at least one capacitor of the one or more capacitors is disposed in at least one of a buried rail trench or at least one of a gate-cut and fin-cut region corresponding at least partially to the STI region.

3. The circuit of claim 2, wherein the at least one capacitor is formed on a storage node of the circuit, wherein the storage node is positioned in one or both of the buried rail trench and the fin-cut region of the circuit.

4. The circuit of claim 2, wherein the at least one capacitor is formed in the STI region and a silicon substrate region of the circuit.

5. The circuit of claim 2, wherein the at least one capacitor is formed perpendicular to a transistor-gate layer configured to form respective gates of first transistor and second transistors.

6. The circuit of claim 2, wherein the at least one capacitor is formed parallel to a transistor-gate layer configured to form respective gates of first transistor and second transistors.

7. The circuit of claim 1, wherein the circuit structure comprises a memory bitcell.

8. The circuit of claim 7, wherein the memory bitcell comprises an eDRAM gain-cell.

9. The circuit of claim 8, wherein the eDRAM gain cell comprises:
a write transistor;
a read transistor; and
and a storage node coupled to a gate of the read transistor, wherein the charge-based storage element comprises a capacitor that is formed on the storage node of the circuit.

10. The circuit of claim 9, wherein a charge of the storage node corresponds to a charge of a gate capacitance of the read transistor.

11. The circuit of claim 1, wherein the circuit structure is configured to store digital data in the charge-based storage element.

12. The circuit of claim 1, wherein the charge-based storage element comprises:
a first liner material; and
a first metal layer disposed on the first liner material.

13. A method comprising:
providing a circuit structure disposed on a substrate and a shallow-trench-isolation (STI) region of a circuit;
forming an opening of the substrate and the STI region by removing a portion of the substrate and STI region;
placing a first liner material in the opening and on remaining portions of the substrate and the STI region; and
depositing a first metal layer in the opening on the first liner material.

14. The method of claim 13, wherein the substrate is coupled to ground, and wherein an input voltage is coupled to the circuit structure, and wherein forming the opening comprises: removing a portion of a field effect transistor.

15. The method of claim 13, further comprising:
placing a second liner material in the opening and on the first metal layer;
depositing a second metal layer in the opening on the second liner material, wherein the input voltage is coupled to the first metal layer.

16. The method of claim 14, further comprising:
enclosing the second metal layer within the second liner material; and
depositing the first metal layer on the second liner material, wherein the first metal layer is separated from the second metal layer.

17. The method of claim 15, wherein a ground connectivity corresponding to the second metal layer is configured for connectivity at either upper or lower portions of the second metal layer.

18. A method comprising:
providing a memory cell structure disposed on a substrate and a shallow-trench-isolation (STI) region;
forming one or more charge-based storage elements in the substrate and the STI region to store data of the memory cell structure; and
manufacturing, or causing to be manufactured, a memory device having the memory cell structure with the one or more charge-based storage element formed in the substrate and the STI region or fin-cut region.

19. The method of claim 18, wherein the one or more charge-based storage elements comprises one or more capacitors.

20. The method of claim 18, memory cell structure comprises an eDRAM gain-cell.
